(19) United States
(12) Patent Application Publication
(10) Pub. No.: US 2026/0190525 A1
(43) Pub. Date: Jul. 2, 2026

(54) IMAGE SENSING DEVICE

(71) Applicant: SK hynix Inc., Icheon-si (KR)

(72) Inventor: Won Jin KIM, Icheon-si (KR)

(21) Appl. No.: 19/196,616

(22) Filed: May 1, 2025

(30) Foreign Application Priority Data
Dec. 30, 2024 (KR) 10-2024-0200572

(51) Int. Cl. H10F 39/00; H10F 39/18

(52) U.S. Cl. CPC H10F 39/8053; H10F 39/182; H10F 39/8063; H10F 39/807

(57) ABSTRACT

An image sensing device may include at least one green pixel, and at least one red pixel. The green pixel may include a first photoelectric conversion element and a first optical structure disposed on the photoelectric conversion element. The red pixel may be disposed adjacent to the green pixel. The red pixel may include a second photoelectric conversion element, and a second optical structure disposed on the second photoelectric conversion element. A thickness of the first optical structure and a thickness of the second optical structure may be substantially the same. An effective refractive index of the first optical structure may be greater than an effective refractive index of the first optical structure.

### CROSS-REFERENCES TO RELATED APPLICATION

This patent document claims the priority and benefits of Korean application number 10-2024-0200572, filed on Dec. 30, 2024, which is incorporated herein by reference in its entirety.

### TECHNICAL FIELD

The technology and implementations disclosed in this patent document relate to an image sensing device.

### BACKGROUND

An image sensing device may include an optical element that converts an optical image into an electrical signal. The optical element may include, for example, a complementary metal oxide semiconductor (CMOS) image sensor. The CMOS image sensor may be integrated into each of the separately defined spaces, referred to as pixels, on a semiconductor substrate.

As the miniaturization and high resolution of image sensing devices are increasingly demanded, a reduction in pixel size is required. However, the reduction in pixel size decreases the area of photo-detectors (e.g., photodiodes) in the pixels. Therefore, light collection efficiency of the photo-detectors may be reduced, which may lead to the degradation of image quality.

### SUMMARY

In some example embodiments, an image sensing device may include a plurality of photoelectric conversion elements configured to convert light into electrical charge and an optical structure disposed between adjacent photoelectric conversion elements among the plurality of photoelectric conversion elements. Each of the photoelectric conversion elements formed in a corresponding pixel region among a plurality of pixel regions partitioned by the pixel isolation layer. The optical structure may be formed on the photoelectric conversion structure. The optical structure may be formed to have a uniform thickness for each of the plurality of pixel regions. The optical structure may include a grid pattern, a plurality of green color filters, a plurality of red color filters, a first micro lens, and a second micro lens. The grid pattern may be formed at a position corresponding to the pixel isolation layer. The plurality of green color filters may be formed in predetermined regions (e.g., green pixel region) of the plurality of pixel regions. The plurality of red color filters may be formed in predetermined regions (e.g., red pixel region) of the plurality of pixel regions. The first micro lens may be formed on the plurality of green color filters. The first micro lens may include a material having a first refractive index. The second micro lens may be formed on the plurality of red color filters. The second micro lens may include a material having a second refractive index lower than the first refractive index.

In some example embodiments, the first micro lens may have a thicker thickness than the second micro lens. An upper surface of the first micro lens may have a flat shape. An upper surface of the second micro lens may have a curvature greater than zero. In some implementations, the term “curvature” can refer to an intrinsic curvature.

In some example embodiments, an image sensing device may include a substrate, a plurality of photoelectric conversion elements, a pixel isolation layer, a grid pattern, a green color filter, a red color filter, a first micro lens and a second micro lens.

In some example embodiments, the substrate may have a front side and a back side. The plurality of photoelectric conversion elements may be formed from the front surface of the substrate towards the rear surface. The pixel isolation layer may be formed in the substrate to optically separate the plurality of photoelectric conversion elements. For example, the pixel isolation layer is disposed between adjacent photoelectric conversion elements. The grid pattern may be formed on the rear surface of the substrate to have a first thickness at a location corresponding to the pixel isolation layer. The green color filter may be disposed in first regions between the grid pattern to be partially overlapped with the grid pattern. The green color filter may be formed to have a second thickness less than the first thickness. The red color filter may be disposed in second regions. The red color filter may be formed to have a third thickness greater than the second thickness and less than the first thickness. The first micro lenses may be formed on the green color filter. The first micro lens may be formed to have a fourth thickness. The second micro lens may be formed on the plurality of red color filters. The second micro lens may be formed to have a fifth thickness smaller than the fourth thickness.

In some example embodiments, an image sensing device may include at least one green pixel and at least one red pixel.

In some example embodiments, the green pixel may include a first photoelectric conversion element configured to convert light into electrical charge and a first optical structure disposed on the photoelectric conversion element. The red pixel may be disposed adjacent to the green pixel. The red pixel may include a second photoelectric conversion element configured to convert light into electrical charge and a second optical structure disposed on the second photoelectric conversion element. A thickness of the first optical structure and a thickness of the second optical structure may be substantially the same. An effective refractive index of the first optical structure may be greater than an effective refractive index of the first optical structure.

In some example embodiments, the first optical structure may include a green color filter formed on the first photoelectric conversion element and a first micro lens formed on the green color filter.

In some example embodiments, the second optical structure may include a red color filter formed on the second photoelectric conversion element and having a thickness greater than the green color filter, and a second micro lens formed on the red color filter and formed of a material having a lower refractive index than the first micro lens.

In some example embodiments, by adjusting the refractive index, thickness, and shape of the micro lenses of the green pixels, the light-collection efficiency of the green pixels can be improved.

### BRIEF DESCRIPTION OF THE DRAWINGS

The above and another aspects, features and advantages of the subject matter of the present disclosure will be more easily understood from the following detailed description taken in conjunction with the accompanying drawings.

FIG. 1 is a block diagram illustrating an image sensing device based on some example embodiments.

FIG. 2 is a cross-sectional view illustrating an image sensing device based on some example embodiments.

FIG. 3 is a cross-sectional view illustrating a photoelectric conversion structure based on some example embodiments.

FIG. 4A is a plan view illustrating a pixel array based on some example embodiments.

FIG. 4B is a cross-sectional view taken along a line A-A′ in FIG. 4A.

FIG. 5A is a plan view illustrating a pixel array based on some example embodiments.

FIG. 5B is a cross-sectional view taken along a line B-B′ in FIG. 5A.

FIG. 6A is a plan view illustrating a pixel array based on some example embodiments.

FIG. 6B is a cross-sectional view taken along a line C-C′ in FIG. 6A.

FIG. 7 is a flow chart illustrating a method of fabricating a pixel array of an image sensing device based on some example embodiments.

FIG. 8 is a flow chart illustrating a method of forming a micro lens array based on some example embodiments.

FIG. 9 is a plan view illustrating an arrangement of color filters based on some example embodiments.

### DETAILED DESCRIPTION

The embodiments of the present application describe, among other features and benefits, techniques for increasing the sensing currents of green pixels, which determines image quality, in image sensing devices that adopt small pixels of about 0.7 μm or smaller.

To increase the sensing current of the green pixels, an effective refractive index of an optical structure for focusing light onto the green pixels may be configured to be higher than the effective refractive index of the optical structure for focusing light onto the red pixels.

In some example embodiments, a thickness of the green color filter, which has a relatively low refractive index compared to the red color filter, may be relatively thin.

In some example embodiments, a first micro lens formed on the green color filter may include a material having a relatively higher refractive index than the second micro lens formed on the red color filter.

In some example embodiments, by increasing the thickness of the first micro lens to be greater than that of the second micro lens, the refractive index of the first micro lens can be increased, preventing the phenomenon of light incident on the green pixel surface from being absorbed by the red pixel surface.

In some example embodiments, by configuring an upper surface of the first micro lens in a flat shape or a similar shape, the incident area on the green pixel surface can be increased.

In some example embodiments, an image sensing device may have the following structural features.

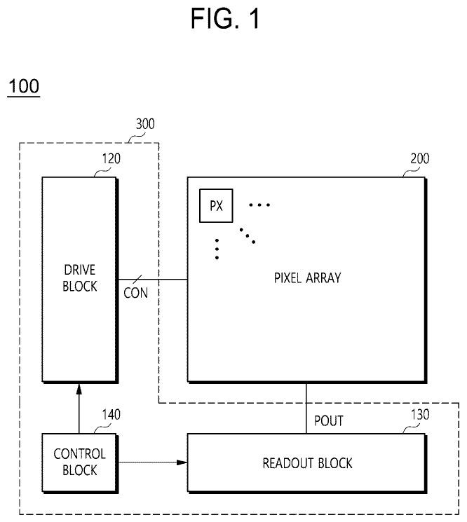

FIG. 1 is a block diagram illustrating an image sensing device based on some example embodiments.

Referring to FIG. 1, an image sensing device 100 may be a CMOS image sensor configured to convert light into an electrical signal. In some example embodiments, the light may include photons that can cause a photoelectric effect. The light may also refer to electromagnetic radiation or electromagnetic waves within specific wavelength bands in the electromagnetic spectrum, including radio waves, microwaves, infrared rays, near-infrared rays, visible light, ultraviolet light, X-rays, and gamma rays.

The image sensing device 100 may include a pixel array 200 and a logic assembly 300. The pixel array 200 may include a plurality of pixels PXs arranged in a matrix and each pixel PX includes a photodetector or a photoelectric conversion element which detects incident light and generates an electrical signal or pixel signal representing the detected incident light.

The logic assembly 300 may include a drive block 120, a readout block 130 and a control block 140.

In some example embodiments, the pixel array 200 may include a plurality of rows and a plurality of columns. The pixels PXs belonging to one of the plurality of rows may receive the same pixel control signal from the drive block 120. The pixels PXs belonging to one of the plurality of columns may be connected to a single column line to output pixel signals to the readout block 130.

The drive block 120 may drive the pixels PXs of the pixel array 200 in response to a timing signal output from the control block 140. For example, the drive block 120 may output at least one control signal (CON) configured to select and control the pixels PXs included in at least one of the plurality of row lines of the pixel array 200.

The readout block 130 may detect a pixel signal Pout output from the pixel array 200 under the control of the control block 140. The readout block 130 may generate image data from the detected pixel signal Pout. The image data may be pixel data in a digital form obtained by performing an analog-to-digital conversion of pixel signals in an analog form. To generate the digital pixel data, the readout block 130 may include a dual correlation sampler (not shown) and an analog-to-digital converter (not shown). The readout block 130 may further include a buffer circuit for temporarily storing the pixel data output from the analog-to-digital converter and outputting the pixel data externally under the control of the control block 140.

The control block 140 may generate timing signals for controlling the operations of the drive block 120 and the readout block 130.

In some example embodiments, the image sensing device 100 may further include an external processor (e.g., image signal processor (ISP), not shown). In one example, the control block 140 may generate timing signals in a timely manner in response to a request from the external processor. In some example embodiments, the control block 140 may include a logic control circuit, a phase lock loop (PLL) circuit, a timing control circuit and a communication interface circuit.

The pixel array 200 and the logic assembly 300 may be formed in a two-dimensional structure, or may be stacked in a three-dimensional structure.

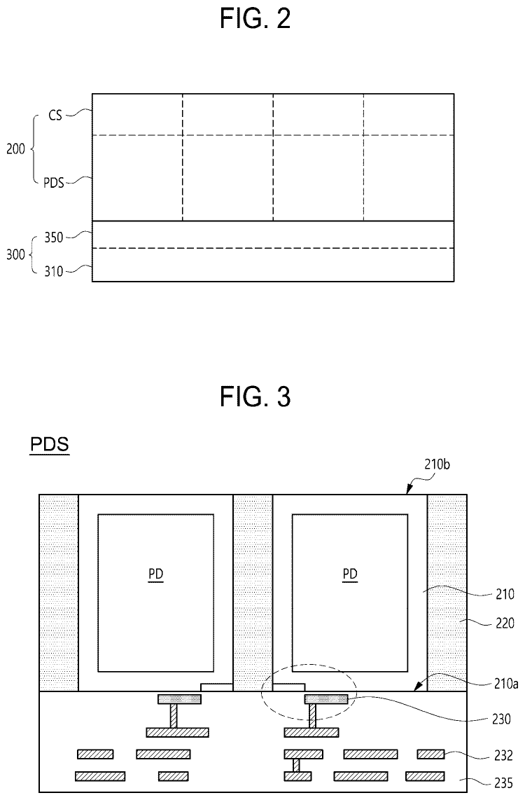

FIG. 2 is a cross-sectional view illustrating an image sensing device based on some example embodiments.

Referring to FIG. 2, the pixel array 200 and logic assembly 300 of the image sensing device 100 may be stacked.

The pixel array 200 may include a photoelectric conversion structure PDS and an optical structure CS sequentially stacked.

The photoelectric conversion structure PDS may include a substrate (not shown) on which a plurality of photoelectric conversion elements may be formed. The plurality of photoelectric conversion elements may be formed on each of the plurality of pixels PXs shown in FIG. 1.

The optical structure CS may be positioned between the photoelectric conversion structure PDS and a light source (not shown). The optical structure CS may focus the incident light emitted from a light source onto the plurality of photoelectric conversion elements.

The logic assembly 300 may include a logic substrate 310 and a logic circuit layer 350. Although not shown in the drawings, the logic circuit layer 350 may include a plurality of transistors, conductive interconnections and insulating layers in the drive block 120, the readout block 130 and the control block 140 of FIG. 1.

In some example embodiments, the pixel array 200 and the logic assembly 300 may be hybrid-bonded to each other such that the photoelectric conversion structure PDS and the logic circuit layer 350 face each other.

FIG. 3 is a cross-sectional view illustrating an example of a photoelectric conversion structure based on some example embodiments.

Referring to FIG. 3, the photoelectric conversion structure PDS may include a substrate 210, a pixel isolation layer 220 and a plurality of photoelectric conversion elements PD.

For example, the substrate 210 may be bulk silicon or silicon-on-insulator (SOI). In another example, the substrate 210 may include germanium silicide, indium antimonide, lead telluride compound, indium arsenide, indium phosphide, gallium arsenide, or gallium antimonide. The substrate 210 may also include an epitaxial growth layer. The substrate 210 may include first or second conductive type impurities. For example, the first conductive type may be the p-type, and the second conductive type may be then-type opposite to the first conductive type. The substrate 210 may include a first surface 210a corresponding to a front side, and a second surface 210b corresponding to a back side.

The pixel isolation layer 220 may be formed in the semiconductor substrate 210. The pixel isolation layer 220 may be formed to be in contact with at least one of the first surface 210a and the second surface 210b of the semiconductor substrate 210. A plurality of unit pixel regions may be defined by the pixel isolation layer 220. For example, the pixel isolation layer 220 may be configured as a deep trench type or a junction type.

The plurality of photoelectric conversion elements PDs may be formed in the substrate 210 corresponding to each of the unit pixel regions. The plurality of photoelectric conversion elements PDs may be separated by the pixel isolation layer 220. For example, the plurality of photoelectric conversion elements PD may be electrical elements configured to generate photoelectric charge corresponding to the incident light. In some example embodiments, the photoelectric conversion elements PD may include a photo diode, a photo transistor, a photo gate, a pinned photo diode (PPD), or a combination thereof.

The pixel array 200 may further include a plurality of pixel transistors 230 configured to convert light detected by the photoelectric conversion elements PD into pixel current, a plurality of floating diffusion regions (not shown), interconnection layers 232 electrically coupled to the plurality of pixel transistors 230, and an insulating interlayer 235 configured to electrically insulate the interconnection layers 232.

The plurality of pixel transistors 230, the plurality of floating diffusion regions, the interconnection layers 232, and the insulating interlayer 235 may be formed on the first surface 210a of the semiconductor substrate 210.

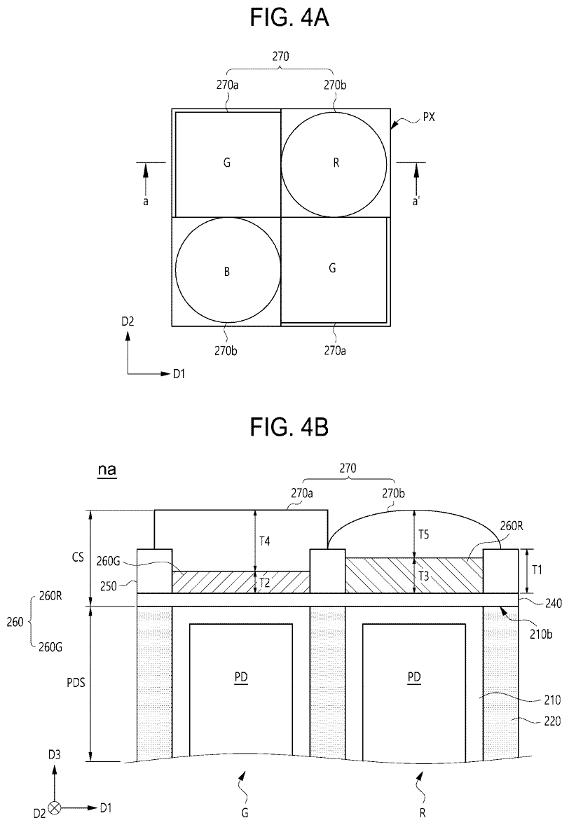

FIG. 4A is a plan view illustrating a pixel array based on some example embodiments, and FIG. 4B is a cross-sectional view taken along a line A-A′ in FIG. 4A.

Referring to FIGS. 4A and 4B, the optical structure CS of the pixel array 200 may be formed on the second surface of the photoelectric conversion structure PDS.

In some example embodiments as shown in FIG. 4B, the optical structure CS may include an anti-reflective layer 240 above photoelectric conversion elements PD, a grid pattern 250, a color filter array 260 of color filters above the anti-reflective layer 240 to selectively filter the colors of light to be received by photoelectric conversion elements PD, and a micro lens array 270 of micro lenses above the color filter array 260 to collect and direct incident light to the underlying the color filter array 260 and the photoelectric conversion elements PD.

The anti-reflective layer 240 may be formed, for example, on the second surface 210b of the substrate 210 on which the photoelectric conversion structure PDS is formed. For example, the anti-reflective layer 240 may include at least one of, but not limited to, silicon oxide, silicon nitride, silicon oxynitride, aluminum oxide, or hafnium oxide, or a combination thereof. Although not shown, at least one insulating interlayer may be further interposed between the anti-reflective layer 240 and the photoelectric conversion structure PDS.

The grid pattern 250 may be formed on the anti-reflective layer 240 to prevent an optical crosstalk between the color filters. The grid pattern 250 may define regions where the color filters will be formed. In some example embodiments, the grid pattern 250 may be formed to overlap the pixel isolation layer 220, at a location corresponding to the pixel isolation layer 220. As a result, the grid pattern 250 may define pixel regions on the optical structure CS.

For example, the grid pattern 250 may include air having a refractive index of 1. For example, the grid pattern 250 may be formed as a stack structure of thin conductive layers and air. However, without limitation, the grid pattern 250 may be formed of a material having a lower refractive index than the micro lenses including the micro lens array. For example, the grid pattern 250 may be formed to have a first thickness T1.

The color filter array 260 may include a plurality of color filters. For example, the plurality of color filters may include color filters of different colors for capturing color information of the images in the incident light and may include, for example, a red color filter 260R, a green color filter 260G and a blue color filter 260B.

In some example embodiments, the plurality of color filters 260R, 260G and 260B may be arranged in a Bayer pattern based on three colors: red, green, and blue with 50% green, 25% red and 25% blue. For example, the color filters 260R, 260G and 260B may be arranged in adjacent pixels PXs along a first direction D1 and a second direction D2, respectively, to filter different colors of light. For example, in the color filter array 260 configured in accordance with the Bayer pattern, the number of green color filters 260G may be greater than the number of red color filters 260R and blue color filters 260B. The reason for relatively increasing the number of green color filters 260G is that the green color filters 260G have a dominant influence on the illuminance.

In some example embodiments, the green color filter 260G may be formed with a second thickness T2 lower than the first thickness T1. The red color filter 260R may be formed with a third thickness T3 smaller than the first thickness T1 and greater than the second thickness T2. The green color filter 260G and the red color filter 260R may be formed with a thickness less than the thickness of the grid pattern 250.

The micro lens array 270 may be formed on the color filter array 260. For example, the micro lens array 270 may include a first micro lens 270a and a second micro lens 270b.

The first micro lens 270a may be formed over the green color filter 260G. The first micro lens 270a may be formed of a material having a first refractive index. For example, the first refractive index may be 1.7 to 1.9. The first micro lens 270a may have a fourth thickness T4. An upper surface of the first micro lens 270a may have a flat surface with a curvature of zero or close to zero.

The second micro lens 270b may be formed over each of the red color filter 260R and the blue color filter 260B. The second micro lens 270b may be formed of a material having a second refractive index lower than the first refractive index of the first micro lens 270a formed over each green color filter 260G. For example, the second refractive index may be 1.5 to 1.7. The second micro lens 270b may have a fifth thickness T5 smaller than the fourth thickness T4. The second micro lens 270b may be formed to have a substantially curved shape to have a hemispherical shape.

Edges of the first and second micro lenses 270a and 270b may partially overlap with the grid pattern 250.

In some example embodiments, the sum of the second thickness T2 and the fourth thickness T4 may be equal to the sum of the third thickness T3 and the fifth thickness T5 within an allowable margin of error. Consequently, for each pixel, a maximum thickness of the optical structure CS may be uniform, assuming that a thickness of the anti-reflective layer 240 is uniform.

For example, the fourth thickness T4 and fifth thickness T5 may range from 1/10 to 1/20 of the wavelength of the incident light. The first and second micro lenses 270a and 270b may be formed of at least one of a resist layer, a thermosetting resin, or an insulating layer to form a flat surface with zero curvature or a surface having a curvature greater than zero.

As mentioned above, when the different color filters 260R, 260G and 260B are disposed between the adjacent pixels PXs, the first micro lens 270a and second micro lens 270b may be alternately disposed along the first and second directions D1 and D2.

For example, the red color filter 260R (e.g., around 650 nm) may have a relatively high refractive index compared to the green color filter 260G (e.g., around 550 nm) in a wavelength band for visible light colors from about 450 nm to about 650 nm. However, when a pixel size may be reduced, light incident on the pixel with the green color filter 260G (hereinafter, green pixel G) having a relatively low refractive index may be absorbed by the pixel with the red color filter 260R (hereinafter referred to as the red pixel R) having a relatively high refractive index. As a result, the amount of light incident on the green pixel G may be reduced, leading to a reduction in the sensing current of the green pixel G, which plays an important role in determining the brightness of the image device.

The disclosed technology can be implemented in some embodiments to compensate for the sensing current of the green pixel G in the small pixel structure by increasing the effective refractive index of the optical structure located at the green pixel G compared to the effective refractive index of the optical structure CS located at the red pixel R. the effective refractive index may be determined in various ways. For example, the effective refractive index may be determined by calculating an average value of the refractive indices of optical materials (such as, a color filter material, etc.) located in a color filter area.

The effective refractive index may vary depending on a thickness ratio of the optical materials located in the color filter area.

In some example embodiments, by modifying the material, thickness, and structure of the first micro lens 270a, the effective refractive index of the optical structure CS of the green pixel G may be increased compared to the effective refractive index of the red pixel R. Accordingly, the light incident on the green pixel G may be prevented from being dispersed toward the neighboring red pixel R.

For example, the first micro lens 270a formed over the green pixel G may be formed with a material having a relatively higher refractive index than the second micro lens 270b formed over the red pixel R (and/or the blue pixel B), while forming the thickness of the first micro lens 270a to be greater than the thickness of the second micro lens 270b within a set range. Accordingly, the effective refractive index of the first micro lens 270a may be increased compared to the effective refractive index of the second micro lens 270b, allowing the light incident on the green pixel G to be efficiently focused onto the photoelectric conversion element PD disposed below the green pixel G without being dispersed toward neighboring pixels.

In some embodiments, the thicknesses T4 and T5 of the first and second micro lenses 270a and 270b may represent thicknesses of the thickest portions of the first and second micro lenses 270a and 270b. For example, the thickness T4 of the first micro lens 270a may be increased compared to the thickness T5 of the second micro lens 270b because the thickness T2 of the green color filter 260G is smaller than the thickness T3 of the red color filter 260R. The thickness of the green color filter 260G having a relatively low refractive index may be smaller than the thickness of the red color filter 260R, so that the effective refractive index of the optical structure of the green pixel G may be further increased. The predetermined range of the first and second micro lenses 270a and 270b may be a range that does not exceed the predetermined thickness of the optical structure.

As the curvature of the first micro lens 270a may be formed to be zero or close to zero, the amount of the light incident perpendicularly onto the surface of the first micro lens 270a may be increased.

As the incident light traveling toward the green pixel G passes through air, a low refractive index medium in which the incident light source may be located, the first micro lens 270a, a medium of higher refractive index than the air, and the grid pattern 250 and/or the green color filter 260G, a medium of lower refractive index compared to the first micro lens 270a, a focal length of the incident light may be changed. Accordingly, even if the surface of the first micro lens 270a may have the flat shape, the incident light may be focused at the photoelectric conversion element PD portion of the green color filter 260G due to the refractive index differences among the media (air, 270a, 260G and 250).

On the other hand, the second micro lens 270b disposed on the red color filter 260R and the blue color filter 260B may include a material having a lower refractive index than the first micro lens 270a, and may be formed to have a larger curvature than the first micro lens 270a. Accordingly, the second micro lens 270b may concentrate the light incident toward the red pixel R and/or the blue pixel B, and absorbs the light incident toward the adjacent green pixel G to a reduced extent.

As the first micro lens 270a and the second micro lens 270b based on some example embodiments may be configured with different shapes, the shapes of the pixels may be clearly distinguished, which may facilitate pixel inspection at the time of the shipment of the image sensing device.

In some example embodiments, the light concentration efficiency of the green pixel G may be increased by forming the first micro lens 270a with the material having the larger refractive index than the second micro lens 270b, while forming the thickness of the first micro lens 270a to be greater than the thickness of the second micro lens 270b. For example, the surface of the first micro lens 270a may be formed to be flat to further increase the light concentration efficiency of the green pixel G.

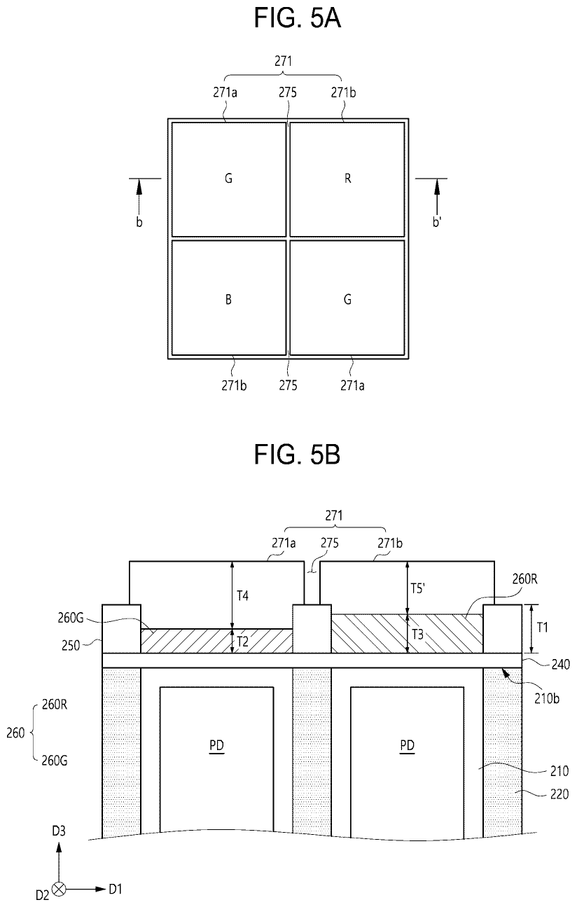

FIG. 5A is a plan view illustrating a pixel array based on some example embodiments, and FIG. 5B is a cross-sectional view taken along a line B-B′ in FIG. 5A. The examples shown in FIGS. 5A and 5B may have the same configuration as the examples shown in FIGS. 4A and 4B, except for the configuration of the micro lens array. Accordingly, the examples below will focus on the modified configuration of the micro lens array.

Referring to FIGS. 5A and 5B, the micro lens array 271 may include a first micro lens 271a, a second micro lens 271b and a lens isolating portion 275.

The first micro lens 271a may be formed on the green pixel G. The second micro lens 271b may be formed on at least one of the red pixel R and/or the blue pixel B.

The first micro lens 271a may be formed of a material having a first index of refraction of 1.7 to 1.9. The second micro lens 271b may be formed of a material having a second index of refraction lower than the first index of refraction, such as 1.5 to 1.7.

The first micro lens 271a may be formed to have a fourth thickness T4. The second micro lens 271b may be formed to have a fifth thickness T5′ smaller than the fourth thickness T4.

Each of the first and second micro lenses 271a and 271b based on some example embodiments may be formed to have a flat surface with a curvature of zero or close to zero.

The lens isolating portion 275 may be positioned on the grid pattern 250. The lens isolating portion 275 may be formed in a groove shape. The depth of the lens isolating portion 275 may be less than the thickness of the first and second micro lenses 271a and 271b positioned on the grid pattern 250.

Accordingly, the lens isolating portion 275 may insert air having a low refractive index between the first and second micro lenses 271a and 271b. Thus, the light incident on a boundary of the first micro lens 271a and the second micro lens 271b may be directed toward the first micro lens 271a, which has the relatively high refractive index, thereby improving the light collection efficiency of the green pixel G. In addition, the pixels may be clearly distinguished by the lens isolating portion 275, which may facilitate the inspection process of the pixels.

In FIG. 5A, the lens isolating portion 275 may be formed in a structure corresponding to the grid pattern 250, but may also be formed in a cross shape at the corners of the pixels R, G and B.

In some example embodiments, both the first micro lens 271a and the second micro lens 271b may be formed to have the flat surface, which may increase the amount of the incident light toward the pixels located at the lower end of the first micro lens 271a and the second micro lens 271b.

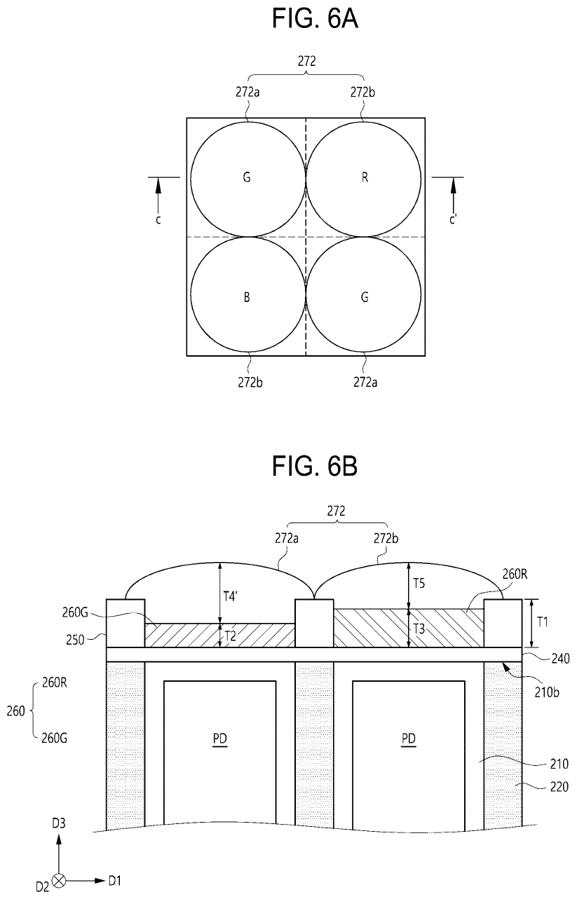

FIG. 6A is a plan view illustrating a pixel array based on some example embodiments, and FIG. 6B is a cross-sectional view taken along a line C-C′ in FIG. 6A. The examples shown in FIGS. 6A and 6B may have the same configuration as the examples shown in FIGS. 4A and 4B, except for the configuration of the micro lens array.

Referring to FIGS. 6A and 6B, the micro lens array 272 may include a first micro lens 272a and a second micro lens 272b.

The first micro lens 271a may be formed on the green pixel G. The second micro lens 271b may be formed on at least one of the red pixel R and/or the blue pixel B.

The first micro lens 271a may be formed of a material having a first index of refraction of 1.7 to 1.9. The second micro lens 271b may be formed of a material having a second index of refraction lower than the first index of refraction, such as 1.5 to 1.7.

The first and second micro lenses 272a and 272b may each be formed to have a curvature and thus have a substantially hemispherical shape. The first micro lens 272a may have a fourth thickness T4′. The second micro lens 272b may be formed to have a fifth thickness T5 smaller than the fourth thickness T4′.

In some example embodiments, because the first micro lens 272a may be formed with a relatively higher refractive index material and a greater thickness than the second micro lens 272b, the light incident toward the green pixel G may be prevented from being absorbed toward the red pixel R and the blue pixel B, even if the first micro lens 272a and the second micro lens 272b may have a substantially identical hemispherical curvature.

Furthermore, as both of the first and second micro lenses 272a and 272b may be configured as hemispherical, the micro lenses may be separated by pixels, which may facilitate pixel inspection.

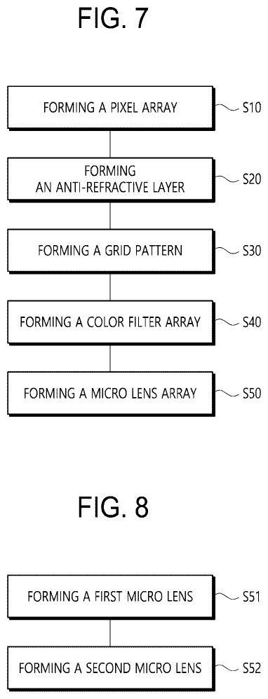

FIG. 7 is a flow chart illustrating a method of fabricating a pixel array of an image sensing device based on some example embodiments. FIG. 8 is a flow chart illustrating a method of forming a micro lens array based on some example embodiments.

Referring to FIG. 7, a pixel array may be formed on a semiconductor substrate S10. For example, the forming of the pixel array S10 may include forming a pixel isolation layer, forming a photoelectric conversion element, and forming pixel transistors.

An anti-reflective layer may then be formed on the pixel array S20.

A grid pattern may be formed on an upper surface of the anti-reflective layer S30. The grid pattern may be formed on a portion corresponding to the pixel isolation layer. For example, the grid pattern may be formed to have a first thickness.

A color filter array may be formed on the grid pattern S40. For example, the forming of the color filter array S40 may include forming a green color filter, forming a red color filter, and forming a blue color filter. Each of the green color filter, red color filter and blue color filter may be formed with a thickness lower than the first thickness. Accordingly, the green color filter, the red color filter and the blue color filter may be completely separated by the grid pattern. In addition, the green color filter may be formed to have a relatively smaller thickness than the red color filter and the blue color filter.

A micro lens array may then be formed on the color filter array S50.

Referring to FIG. 8, the forming of the micro lens array may include forming a first micro lens over the green color filter S51, and forming a second micro lens over the red color filter S52. The first micro lens may be formed with a larger refractive index and a larger thickness than the second micro lens. The first micro lens and the second micro lens may have a flat surface with zero curvature or a curvature greater than zero. The forming of the first micro lens and the forming of the second micro lens may be carried out with different materials and different process methods.

Where each of the first micro lens and the second micro lens has the flat surface, the first micro lens and the second micro lens may be formed by forming a lens isolating portion on at least a portion between the first and second micro lens after the first and second micro lenses are separately formed with different materials.

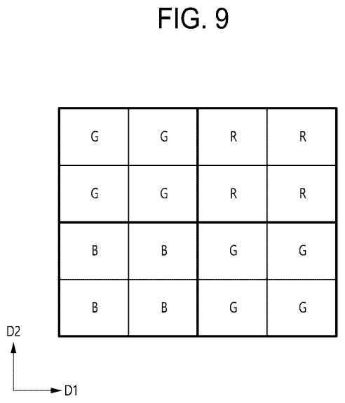

FIG. 9 is a plan view illustrating a color filter array based on some example embodiments.

The example embodiments discussed with reference to FIGS. 4A to 6B relate to an example where four unit pixels constitute a pixel group, and two green pixels, one red pixel, and one blue pixel are arranged in a Bayer pattern within the pixel group. However, the disclosed technology is not limited to this arrangement and can also be applied to cases where the same color filter is assigned to each pixel group, as shown in FIG. 9.

As explained above, in some example embodiments, the refractive index, thickness, shape of the micro lenses of the green pixels may be adjusted to improve the light collection efficiency of the green pixels.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
a photoelectric conversion structure including a plurality of photoelectric conversion elements configured to convert light into electrical charge and a pixel isolation layer disposed between adjacent photoelectric conversion elements among the plurality of photoelectric conversion elements, each of the photoelectric conversion elements disposed in a corresponding pixel region among a plurality of pixel regions partitioned by the pixel isolation layer; and
an optical structure disposed over the photoelectric conversion structure and having a uniform thickness for each of the plurality of pixel regions,
wherein the optical structure comprises:
a grid pattern disposed at locations corresponding to the pixel isolation layers;
a plurality of green color filters disposed over green pixel regions among the plurality of pixel regions;
a plurality of red color filters disposed over red pixel regions among the plurality of pixel regions;
a first micro lens disposed over the plurality of green color filters and including a material having a first refractive index; and
a second micro lens disposed over the plurality of red color filters and including a material having a second refractive index lower than the first refractive index.

2. The image sensing device of claim 1, wherein the first micro lens has a thickness greater than a thickness of the second micro lens.

3. The image sensing device of claim 1, wherein thicknesses of the plurality of green color filters and the plurality of red color filters are smaller than a thickness of the grid pattern, and
wherein the thickness of the plurality of green color filters is smaller than the thickness of the plurality of red color filters.

4. The image sensing device of claim 1, wherein an upper surface of the first micro lens has a flat shape, and
wherein an upper surface of the second micro lens has a curvature greater than zero.

5. The image sensing device of claim 1, wherein each of the first micro lens and the second micro lens includes a flat upper surface.

6. The image sensing device of claim 5, further comprising:
a lens isolating portion configured to includes air between the first micro lens and the second micro lens.

7. The image sensing device of claim 1, wherein each of upper surfaces of the first and second micro lenses has a curvature.

8. The image sensing device of claim 1, wherein the first micro lens has a refractive index of 1.7 to 1.9,
wherein the second micro lens has a refractive index of 1.5 to 1.7, and
wherein the grid pattern comprises an air layer.

9. An image sensing device comprising:
a substrate having a front side and a back side;
a plurality of photoelectric conversion elements disposed in the substrate to convert light into electrical charge;
a pixel isolation layer disposed in the substrate to optically isolate the plurality of photoelectric conversion elements;
a grid pattern disposed on the back side of the substrate to have a first thickness at a location corresponding to the pixel isolation layer;
a green color filter disposed in at least one first area between the grid patterns, and having a second thickness smaller than the first thickness;
a plurality of red color filters disposed in at least one second area between the grid patterns, and having a third thickness greater than the second thickness and smaller than the first thickness;
a first micro lens disposed to have a fourth thickness on the green color filter; and
a second micro lens disposed on the red color filter to have a fifth thickness smaller than the fourth thickness.

10. The image sensing device of claim 9, wherein a sum of the second thickness and the fourth thickness is the same as a sum of the third thickness and the fifth thickness.

11. The image sensing device of claim 9, wherein a refractive index of the first micro lens is greater than a refractive index of the second micro lens.

12. The image sensing device of claim 9, wherein the first micro lens has a refractive index of 1.7 to 1.9,
wherein the second micro lens has a refractive index of 1.5 to 1.7,
wherein the grid pattern comprises an air layer, and
wherein edges of the first micro lens and the second micro lens overlap with the grid pattern.

13. The image sensing device of claim 9, wherein an upper surface of the first micro lens is flat, and wherein an upper surface of the second micro lens has a curvature greater than zero.

14. An image sensing device comprising:
at least one green pixel including a first photoelectric conversion element configured to convert light into electrical charge, and a first optical structure disposed on the first photoelectric conversion element; and
at least one red pixel disposed adjacent to the green pixel, the at least one red pixel including a second photoelectric conversion element configured to convert light into electrical charge, and a second optical structure disposed on the second photoelectric conversion element,
wherein the first optical structure and the second optical structure have a same thickness, and wherein the first optical structure has an effective refractive index greater than an effective refractive index of the second optical structure.

15. The image sensing device of claim 14, wherein the first optical structure comprises:
a green color filter disposed on the first photoelectric conversion element; and
a first micro lens disposed on the green color filter.

16. The image sensing device of claim 15, wherein the second optical structure comprises:
a red color filter disposed on the second photoelectric conversion element and having a thickness greater than the green color filter; and
a second micro lens disposed on the red color filter and including a material having a refractive index lower than a refractive index of the first micro lens.

17. The image sensing device of claim 15, wherein an upper surface of the first micro lens has a flat shape, and wherein an upper surface of a second micro lens has one of a flat shape and a shape having a curvature greater than zero.

18. The image sensing device of claim 16, further comprising:
a grid pattern disposed between the green color filter and the red color filter to optically separate the green color filter from the red color filter.

19. The image sensing device of claim 18, wherein edge regions of the first and second micro lenses overlap with the grid pattern, and wherein the grid pattern includes a material having a refractive index lower than a refractive index the first and second micro lenses.

20. The image sensing device of claim 18, wherein the grid pattern comprises an air layer.
